(19) United States
(12) Patent Application Publication
(10) Pub. No.: US 2005/0264377 A1
(43) Pub. Date: Dec. 1, 2005

(54) Integrated rotary connector and dynamic RF shield

(76) Inventors: G. David Faulkner, Groveland, MA (US); Keith W. Spellenberg, Pepperell, MA (US); Brian P. McLaughlin, Windham, NH (US)

Correspondence Address: Ronald J. Kisicki, Esq.;JAECKLE FLEISCHMANN & MUGEL, LLP, Suite 200, 39 State Street, Rochester, NY, 14614-1310, US

(21) Appl. No.: 10/854,322

(22) Filed: May 25, 2004

(51) Int. Cl. H03H 9/64

(52) U.S. Cl. 333/193

(57) ABSTRACT

A rotary cable connector assembly for connecting coaxial waveguides. The assembly includes a metal stator having a counterbored well and a metal rotor extending coaxially into the well. An axial air gap is formed between the stator and rotor which each contain a conventional dielectric sleeve and center element for mating conventionally to carry a signal therebetween. An electrical connector/dynamic RF shield for providing an electrical path across the rotary joint and for shielding the air gap includes a pair of rings having crenelated cylindrical leaves extending axially toward each other and being interspersed. Each ring has a face for making electrical contact with the stator and rotor. A spring urges the rings into contact with the stator and rotor. The crenelated leaves provide RF shielding of the air gap surrounded by the shield. The rings are formed of bronze or other non-precious metal or alloy.

### TECHNICAL FIELD

The present invention relates to rotatable electrical contact devices; more particularly, to such devices for permitting rotation of coaxial cable connections; and most particularly, to an improved rotatable contacting electrical connector and RF shield for a coaxial cable.

### BACKGROUND OF THE INVENTION

Devices for permitting rotation of coaxial cable connections between a stator assembly and a rotor assembly are well known. These devices provide a current path through the rotating joint typically through the use of a slip ring connector. The device must also protect the circuit from undesirable RF interference. See, for example, U.S. Pat. Nos. 4,020,431; 4,298,850; and 5,805,115.

In the last-cited patent, a rotary joint for coaxial cable is disclosed and shown in FIG. 7 therein. A stationary tubular metal center conductor is disposed in a cylindrical dielectric sleeve within a metal stator. A metal rotor includes a similar cylindrical dielectric sleeve having a cylindrical recess for receiving a portion of the stationary center conductor extending from the stator. An insulated rotary center conductor extends from the rotor and is received within the stationary conductor wherein the two conductors are capacitively coupled. During relative rotation of the rotor and stator assemblies, the rotary center conductor rotates within the stationary center conductor and the rotor dielectric sleeve rotates outside the stationary center conductor. The disclosure notes that “metal construction of the stator and rotor provide an excellent r.f. shield for the stationary center conductor . . . the dielectric sleeves insulate the stationary conductor from the stator and rotor, respectively.”

A shortcoming of any such arrangement, however, is that, although the arrangement provides an adequate current path across the rotating joint, an air gap exists between the metal housings of the stator and rotor, which function additionally as the RF shielding for the joint. The missing shielding permits undesirable signal leakage from the joint through the gap.

What is needed in the art is a rotary contact means for maintaining RF shielding throughout a rotary cable joint.

What is further needed in the art is a rotary cable connector assembly wherein the air gap between a stator and a rotor is RF shielded.

What is further needed in the art is an electrical connector that also functions as an RF shield.

### SUMMARY OF THE INVENTION

Briefly described, a rotary cable connector assembly in accordance with the invention includes a metal stator having a counterbored well and a metal rotor extending coaxially into the well. The stator and rotor are separated by an annular space containing a duplex ball bearing assembly, permitting the rotor to turn coaxially within the stator. First annular stops on the stator and rotor fix the axial position of the bearing assembly and hence of the stator and rotor with respect to each other, an axial air gap being defined therebetween. The stator and rotor each contain a conventional dielectric sleeve and center element for mating conventionally and rotatably to carry a signal therebetween. Second annular stops on the stator and rotor are disposed on opposite sides of the air gap and define an axial slip contact and pressure faces for a spring-biased electrical contact across the joint. The spring biased electrical contact surrounding the air gap also serves as a dynamic RF shield.

The integrated electrical contact and dynamic RF shield comprises a pair of rings, each ring having crenelated cylindrical leaves extending axially therefrom, the rings being coaxially disposed such that their respective leaves are interspersed. Each ring comprises a flange having an outer axial face, for making electrical contact with one of the axial slip contact faces, and an inner axial face acting as a seat for a coil spring disposed in axial compression around the crenelations and between the rings. The spring urges the outer axial faces into firm electrical contact with the slip contact faces to assure electrical continuity across the rotating joint, and the interspersed crenelated leaves provide RF shielding of the air gap surrounded by the connector. Preferably, the crenelated rings are formed of bronze or other suitable non-precious metal or alloy.

### BRIEF DESCRIPTION OF THE DRAWINGS

The present invention will now be described, by way of example, with reference to the accompanying drawings, in which:

FIG. 1 is an elevational cross-sectional view of a rotary cable connector assembly in accordance with the invention; and

FIG. 2 is an isometric view of a dynamic RF shield for shielding the air gap shown in FIG. 1.

### DESCRIPTION OF THE PREFERRED EMBODIMENTS

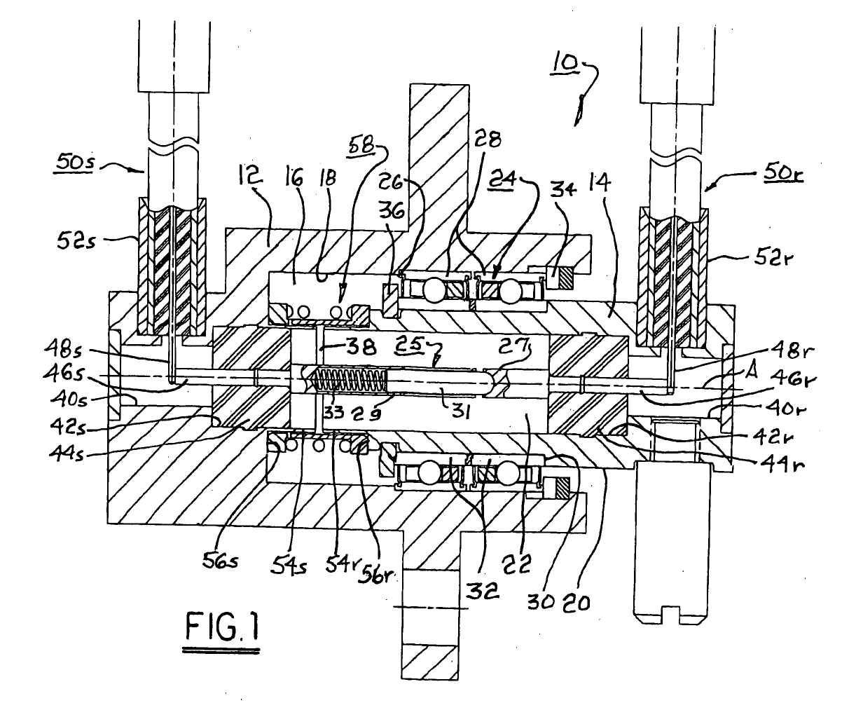

Referring to FIG. 1, a rotary cable connector assembly 10 in accordance with the invention includes a stator body 12 and a rotor body 14. It should be noted that the terms “stator” and “rotor” are arbitrary and in any given application either of elements 12 and 14 may be fixed and the other rotational relative thereto. Stator body 12 includes a first cylindrical well 16 having an inner wall 18. Rotor body 14 has a stepped outer surface 20 and includes a second cylindrical well 22. A duplex ball bearing assembly 24 is disposed between wall 18 and surface 20 to permit bodies 12,14 to rotate axially of each other as desired. Preferably, wall 18 is stepped 26 to receive outer bearing races 28, and surface 20 is similarly stepped 30 to receive inner races 32. The bearing assembly 24 is bounded by first annular stops 34,36 mounted on wall 18 and surface 20, respectively, defining the axial relationship between stator body 12 and rotor body 14 and an axial air gap 38 therebetween.

Bodies 12 and 14 are each provided with an axial bore 40s, 40r and counterbore 42s,42r. A dielectric sleeve 44s,44r is disposed in each of the counterbores. A center conductor 46s,46r is axially disposed in each dielectric sleeve and extends into contact with an orthogonal center conductor 48s,48r of a coaxial transmission element 50s,50r, such as a coaxial cable or other known waveguide, disposed in a fitting 52s,52r. Bodies 12 and 14 are further provided with cylindrical snouts 54s,54r defining second annular stops 56s,56r for telescopically receiving a integrated electrical connector/dynamic RF shield 58 in accordance with the invention for transmitting current across the rotating joint and RF shielding of air gap 38.

Within second well 22, a coaxial center conductor element sub-assembly 25 extends from center conductor 46s, and a coaxial center conductor seat 27 extends from center conductor 46r. Sub-assembly 25 includes a tubular guide 29 slidably housing a connecting pin 31 urged into rotatable mating contact with seat 27 by a spring 33. As shown in FIG. 1, bodies 12 and 14 are disposed coaxially along axis A.

In operation, connector/shield 58 serves as an electrical connector across the rotating joint for powering, for example, the rotating motor. Connector/shield 58 also serves as a shield against undesirable RF interference, which will now be described in greater detail.

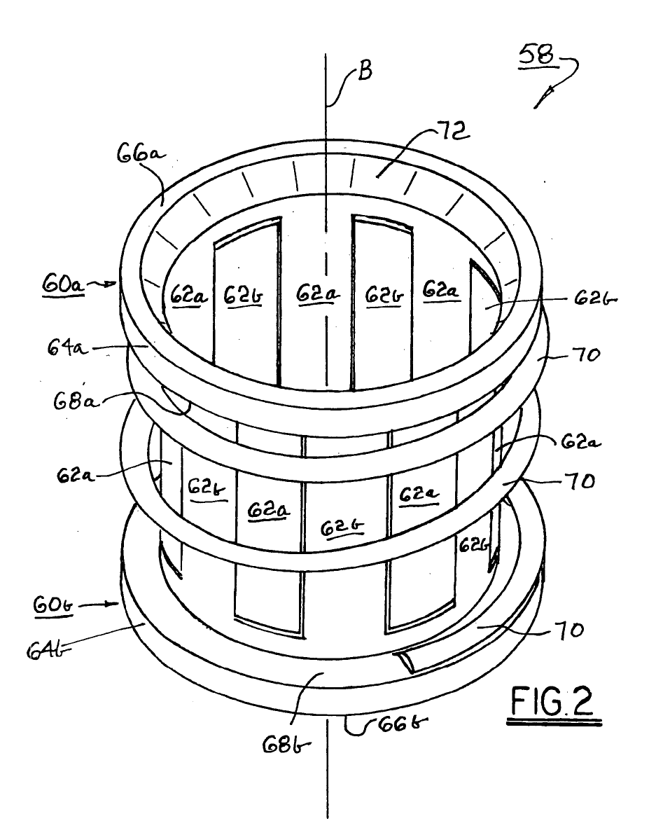

Referring to FIG. 2, connector/shield 58 comprises first and second rings 60a,60b, each ring having at least one, and preferably several, crenelated cylindrical leaves 62a,62b. The leaves extend axially from the rings toward each other in opposite directions, the rings being coaxially disposed along axis B, such that their crenelated leaves are annularly interspersed. Each ring 60a,60b comprises a flange 64a,64b having an outer axial face 66a,66b, for making electrical contact with one of the second annular stops 56s,56r, and an inner axial face 68a,68b acting as a seat for a coil spring 70 disposed in axial compression around the crenelated leaves and between the rings. Crenelated leaves 62a,62b are free to slide past each other axially as required to position shield 58 between stops 56s,56r during installation and assembly of connector assembly 10. The spring urges the outer axial faces into firm electrical contact with the stops, and the interspersed crenelated leaves provide RF shielding of air gap 38 surrounded by the connector. When connector/shield 58 is assembled in connector assembly 10, shield axis B lies coaxially along axis A of bodies 12 and 14.

Preferably, the crenelated rings and leaves are formed of bronze or other non-precious metal or alloy suitable for use as an electrical connector. The spring may be formed of spring steel or other alloy such as beryllium copper.

Preferably, each ring includes a chamfered entrance 72 to facilitate installation onto snouts 54s,54r.

While the invention has been described by reference to various specific embodiments, it should be understood that numerous changes may be made within the spirit and scope of the inventive concepts described. Accordingly, it is intended that the invention not be limited to the described embodiments, but will have full scope defined by the language of the following claims.

1. An electrical connector/RF shield for a rotary RF connector assembly, comprising:
a) a first ring having an axis and having at least one first leaf extending axially therefrom in a first axial direction;
b) a second ring disposed coaxially of said first ring and having at least one second leaf extending axially therefrom in a second and opposite axial direction such that said first and second leaves are angularly adjacent and annularly interspersed about said axis; and
c) a spring disposed between said first and second rings.

2. A connector/shield in accordance with claim 1 comprising a plurality of said first and second leaves.

3. A connector/shield in accordance with claim 1 wherein each of said first and second rings includes an outer axial face for making electrical contact with said rotary RF connector assembly.

4. A connector/shield in accordance with claim 1 wherein said spring comprises a coil spring disposed between said first and second rings and surrounding said first and second leaves.

5. A connector/shield in accordance with claim 4 wherein each of said rings includes an inner axial face for receiving said coil spring.

6. A connector/shield in accordance with claim 1 wherein said first and second rings and leaves are formed from bronze.

7. A rotary RF connector assembly, comprising:
a) a stator body having an axis and an axial well;
b) a rotor body disposed coaxially of said stator body in said well;
c) an air gap between said stator body and said rotor body; and
d) an RF shield surrounding said air gap, said shield including,
a first ring coaxially disposed on one of said stator body and said rotor body against a first stop thereupon and having at least one first leaf extending axially therefrom in a first axial direction,
a second ring coaxially disposed on the other of said stator body and said rotor body against a second stop thereupon and having at least one second leaf extending axially therefrom in a second and opposite axial direction such that said first and second leaves are angularly adjacent and annularly interspersed about said axis, and
a spring urging said first and second rings apart and against said first and second stops.
